(19) United States
(12) Patent Application Publication
(10) Pub. No.: US 2023/0290899 A1
(43) Pub. Date: Sep. 14, 2023

(54) METHOD FOR PLANARIZING CIS-BASED THIN FILM, CIS-BASED THIN FILM MANUFACTURED USING THE SAME, AND SOLAR CELL COMPRISING CIS-BASED THIN FILM

(71) Applicant: KOREA INSTITUTE OF SCIENCE AND TECHNOLOGY, Seoul (KR)

(72) Inventors: Doh Kwon LEE, Seoul (KR); Seung Tae KIM, Seoul (KR); Byoung Soo YU, Seoul (KR); Yoon Hee JANG, Seoul (KR); Jeung Hyun JEONG, Seoul (KR)

(21) Appl. No.: 17/311,999

(22) PCT Filed: Nov. 30, 2020
(86) PCT No.: PCT/KR2020/017297

§ 371 Date: Jun. 9, 2021

(30) Foreign Application Priority Data
Nov. 30, 2020 (KR) 10-2020-0164472

(51) Int. Cl. H01L 31/18; C25F 3/30

(52) U.S. Cl. CPC H01L 31/186; C25F 3/30; H01L 31/0322

(57) ABSTRACT

The present invention relates to a method for planarizing a CIS-based thin film, the method including: electropolishing a CIS-based compound layer by applying current or voltage to an electrochemical cell including: a CIS-based compound layer provided on a conductive base material, as a working electrode; a counter electrode; and an electrolyte solution including a precursor of elements constituting the CIS-based compound layer, a supporting electrolyte, a complexing agent, and an additive including a hydroxy functional group.

### TECHNICAL FIELD

The present invention relates to a method for planarizing a CIS-based thin film, a CIS-based thin film manufactured using the same, and a solar cell comprising the CIS-based thin film.

### BACKGROUND ART

Currently, most of the solar cell market is occupied by crystalline silicon solar cells, but requirement of stable supply and demand of raw materials and limitation in cost reduction caused by expensive initial capital investment and maintenance cost have been pointed out as problems. Meanwhile, interest and investment in thin film solar cells, which have a wide range of applications, are gradually increasing due to the fact that they are able to consume relatively less raw material and be light-weighted than silicon solar cell, and therefore, the proportion of thin film solar cells in the entire solar cell market is increasing year by year.

Among thin film solar cells, copper indium selenide (CIS, CuInSe₂) or copper indium gallium selenide (CIGS, Cu(In₁₋ₓGaₓ)Se₂) solar cells have a photoelectric conversion efficiency of 20% or more, which is high compared to those of other thin film solar cells, and because these efficiencies are expected to be enhanced to the levels of polycrystalline silicon solar cells, the CIS or CIGS solar cells have drawn attention as an alternatives to crystalline silicon solar cells. In addition, as a part of the cost reduction of CIGS solar cells, there are active attempts to replace expensive indium (In) and gallium (Ga) with inexpensive general-purpose elements such as zinc (Zn) and tin (Sn), and in this case, a photoactive layer is represented by copper zinc tin sulfide (CZTS, Cu₂ZnSnS₄). Meanwhile, it is known that the power conversion efficiency of a CIGS solar cell can be enhanced by substituting all or part of selenium (Se) with sulfur (S).

Methods for manufacturing a CIS, CIGS, or CZTS (hereinafter, commonly referred to as “CIS-based”) light absorption layer may be classified into three types, and there are i) a co-evaporation method for evaporating constituent elements and depositing the elements on a base material, and simultaneously inducing a compound formation reaction, ii) a sputtering-selenization method for producing compounds through a separate heat treatment after depositing constituent elements on the base material by sputtering, iii) a method for obtaining a dense thin film through a heat treatment after forming a coating layer by a non-vacuum method, and the like.

Recently, perovskite-based tandem solar cells such as Si/perovskite, CIGS/perovskite, and perovskite/perovskite have overcome the efficiency limit of single-junction solar cells and are considered as a next-generation solar cell technology that can be commercialized. Among them, thin film based tandem solar cells are expected to be positioned as a technology capable of actively meeting energy production demand in the urban solar field in the future, based on the potential to overcome the consumer acceptability limit of existing Si solar cells.

CIS-based thin-film solar cells are positioned as bottom cells of thin film tandem solar cells thanks to their high efficiency (23.4%), long-term stability of 20 years or more, and easy controlling the band gap through the adjustment of the composition of In and Ga or Se and S among the constituent elements, but the improvement in efficiency of thin-film based tandem solar cells is slow because there are more limitations in processes than when Si solar cells are applied as bottom cells. One of the main causes for this is the rough surface characteristic of a deposited thin film due to the nature of a material and a manufacturing process of a chalcogenide-based thin film solar cell, and when a perovskite top cell is prepared on a CIS-based bottom cell by a solution process, it may be difficult to conformal deposition according to the surface roughness of the bottom cell, which may lead to decrease in efficiency of a monolithic integrated tandem solar cell by causing degradation of a fill factor, and the like.

Therefore, in order to reduce the surface roughness of a CIS-based bottom cell, a technology of smoothing a recombination layer by chemical mechanical polishing (CMP) process or forming a conformal layer rather than morphology control by atomic layer deposition (ALD) or self-assembled monolayer has been applied, but these technologies have a problem of degrading the performance of the bottom cell by causing mechanical (physical) or chemical damage to a junction part (recombination layer) of a CIS-based thin film tandem solar cell.

### RELATED ART DOCUMENTS

### Prior Art Document

[Patent Document]
(Patent Document 0001) Korean Patent No. 10-1327536

### DISCLOSURE

### Technical Problem

To solve the aforementioned problems, the present invention has been made in an effort to provide a method capable of planarizing the surface of a CIS-based thin film without mechanical (physical) or chemical damage using electropolishing.

### Technical Solution

An exemplary embodiment of the present invention provides a method for planarizing a CIS-based thin film, the method including: electropolishing a CIS-based compound layer by applying current or voltage to an electrochemical cell including: a CIS-based compound layer provided on a conductive base material, as a working electrode; a counter electrode; and an electrolyte solution including a precursor of elements constituting the CIS-based compound layer, a supporting electrolyte, a complexing agent, and an additive including a hydroxy functional group.

Another exemplary embodiment of the present invention provides a CIS-based thin film manufactured using the method.

Still another exemplary embodiment of the present invention provides a thin film solar cell including the CIS-based thin film as a light absorption layer.

### Advantageous Effects

The method for planarizing a CIS-based thin film according to the present invention has the advantages of being able to prevent the CIS-based thin film from being peeled off from a conductive base material even during the electropolishing and reduce the surface roughness of the CIS-based thin film layer to flatten the CIS-based thin film layer, by including an additive including a hydroxy functional group in an electrolyte. Further, when the method for planarizing a CIS-base thin film according to the present invention is used, there is also an advantage of being able to prevent mechanical (physical) or chemical damage to a bottom cell including a junction layer and a CIS-based thin film because a process of smoothing a junction layer (recombination layer), which is essential upon the manufacture of a tandem solar cell based on a solution process, does not need to perform.

### DESCRIPTION OF DRAWINGS

FIG. 1 illustrates a scanning electron microscope (SEM) image of the surface of a CIS-based compound layer manufactured as in Comparative Example 1.

FIG. 2 illustrates the results according to electropolishing in Comparative Example 2.

FIG. 3 illustrates the electropolishing results in the Example according to the content of ethanol.

FIG. 4 illustrates the scanning electron microscope (SEM) images of the surfaces and cross-sections of CIS-based compound layers according to Comparative Example 1 and the Example (0.6 V).

FIG. 5 illustrates the results of measuring the surface roughnesses of the CIS-based compound layers according to Comparative Example 1, Comparative Example 2, and the Example, using an atomic force microscope (AFM).

### MODES OF THE INVENTION

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

Hereinafter, the present invention will be described in detail.

An exemplary embodiment of the present invention provides a method for planarizing a CIS-based thin film, the method including: electropolishing a CIS-based compound layer by applying current or voltage to an electrochemical cell including: a CIS-based compound layer provided on a conductive base material, as a working electrode; a counter electrode; and an electrolyte solution including a precursor of the elements constituting the CIS-based compound layer, a supporting electrolyte, a complexing agent, and an additive including a hydroxy functional group.

According to an exemplary embodiment of the present invention, the additive including the hydroxy functional group may be a C1 to C10 alcohol. Specifically, the additive including the hydroxy functional group may be ethanol. The additive including the hydroxy functional group may prevent peeling of the CIS-based compound layer caused by oxidation or damage of the conductive base material. Further, it is possible to realize an effect of widening the process window for electropolishing such as the applied voltage or improving the surface polishing characteristics of the CIS-based compound layer compared to the case where an electrolyte solution without the additive including the hydroxy functional group is used.

According to an exemplary embodiment of the present invention, a content of the additive including the hydroxy functional group may be 0.5 vol % to 20 vol % in the electrolyte solution. Specifically, a content of the additive including the hydroxy functional group may be 0.5 vol % to 10 vol %, or 1 vol % to 5 vol %, in the electrolyte solution. When the content of the additive including the hydroxy functional group is within the above range, the surface of the CIS-based compound layer may be uniformly polished during the electropolishing by minimizing a change in pH of the electrolyte solution.

According to an exemplary embodiment of the present invention, a pH of the electrolyte solution may be 2.0 to 2.2. When the pH is within the above range, the surface of the CIS-based compound layer may be uniformly polished during the electropolishing.

According to an exemplary embodiment of the present invention, the applied voltage (vs. Ag/AgCl) in the electropolishing step may be 0.4 V to 0.8 V. Specifically, the applied voltage (vs. Ag/AgCl) in the electropolishing step may be 0.4 V to 0.8 V, or 0.5 V to 0.7 V, or 0.55 V to 0.65 V. When the applied voltage is less than the aforementioned range, electropolishing may not be effectively performed, and when the applied voltage exceeds the aforementioned range, a peeling phenomenon of the CIS-based compound layer may occur due to oxidation of the conductive base material. The applied voltage in the electropolishing step may be a constant voltage.

In addition, according to an exemplary embodiment of the present invention, when the applied voltage (vs. Ag/AgCl) in the electropolishing step is an alternating current voltage, the applied voltage (vs. Ag/AgCl) may be 0 V to 0.5 V.

According to an exemplary embodiment of the present invention, the electropolishing step may be determined based on the amount of material to be removed from the surface by polishing. While the electropolishing is being performed, the amount of electric charge may be calculated from the current flowing through a working electrode, and the degree to which an oxidation reaction proceeds may be obtained by the following Reaction Scheme (1).

Cu²⁺+In³⁺+2H₂SeO₃+8H⁺+13e↔CuInSe₂+6H₂O (1)

Electropolishing may be performed such that the amount of CIS-based material removed from the CIS-based compound layer by the oxidation reaction is 1% to 10% of the material of the CIS-based compound layer formed on the working electrode. From this, the electropolishing step may be performed for 5 minutes to 150 minutes. Specifically, the electropolishing step may be performed for 5 minutes to 30 minutes, 5 minutes to 20 minutes, or 7 minutes to 15 minutes. When the electropolishing time is less than the above range, electropolishing may not be effectively performed, and when the electropolishing time exceeds the above range, a peeling phenomenon of the conductive base material and the CIS-based compound layer may occur.

According to an exemplary embodiment of the present invention, the CIS-based compound layer may include a copper indium selenide (CIS) compound, a copper indium gallium selenide (CIGS) compound, or a copper zinc tin sulfide (CZTS) compound.

According to an exemplary embodiment of the present invention, the precursor may be a chloride, sulfate, nitrate, acetate or hydroxide of a metal selected from the group consisting of In, Ga, Zn, Sn, Al, and an alloy thereof, or SeO₂, H₂SeO₃, or SeCl₄. Specifically, when a precursor of Cu, In and Se is used as the precursor, an atomic ratio of Cu, In and Se in the electrolyte solution is 0.8 to 1.2:1 to 5:1.8 to 2.2, more preferably 1:4:2.

Furthermore, the precursor may serve as an initiator for electropolishing. The precursor dissolved in the electrolyte solution, as an initiator, may improve the effect and speed of electropolishing by reducing the resistance at the interface between the surface of the CIS-based compound layer and the electrolyte solution. When the concentration of the precursor is high, the potential at which the oxidation reaction of the CIS-based material occurs is increased, so that electropolishing may not be effectively performed.

According to an exemplary embodiment of the present invention, the supporting electrolyte is for increasing the electrical conductivity of an electrolyte solution, and a material such as potassium chloride (KCl) or lithium chloride (LiCl) may be used, the complexing agent is a material for adjusting the mobility of specific ions in an electrolyte solution, and it is possible to use, for example, triethanolamine (N(CH₂CH₂OH)₃), citric acid (C₆H₈O₇), tartaric acid (C₄H₆O₆), sulfamic acid (NH₂SO₃H), sodium citrate (Na₃C₆H₅O₇), potassium hydrogen phthalate (CsH₅KO₄), potassium thiocyanate (KSCN), or a mixture thereof, but the supporting electrolyte and the complexing agent are not limited thereto. The complexing agent may be added in an appropriate amount to maintain the pH of the electrolyte solution to 2.0 to 2.2, and when the amount of complexing agent added is excessive, the properties of the solution may vary, such as an increase in viscosity of a solution, and a decrease in ion mobility, or corrosion of an electrode arises, such that electropolishing may not be effectively performed. When the amount of complexing agent added is small, the pH of the electrolyte solution may fluctuate during the electropolishing, or hydroxides such as In(OH)₃ may be formed in a high pH range, such that the stability of the electrolyte solution may be reduced.

According to an exemplary embodiment of the present invention, the conductive base material may be soda lime glass coated with molybdenum. Molybdenum is a material widely used as a back electrode layer in CIS-based or similar chalcogenide-based compound solar cells. Therefore, the conductive base material may be used as a back electrode of a solar cell, and a molybdenum layer having characteristics, such as film thickness, resistance, and adhesive strength, suitable for a solar cell manufacturing process may be used.

According to an exemplary embodiment of the present invention, the CIS-based compound layer may be manufactured by a vacuum process such as a vacuum evaporation method, a sputtering method or an atomic layer deposition method, or a non-vacuum process such as a solution process method or an electrochemical deposition method. The composition of copper in a CIS-based thin film for use as a light absorption layer of a solar cell requires a lower composition ratio than a stoichiometric composition, that is, a copper-deficient composition. When there is an excess of copper, a highly conductive secondary phase such as Cu₂₋ₓ Se can be formed and shunt loss may be caused, such that secondary phase etching using a potassium cyanide (KCN) solution may be utilized along with adjusting the composition of the thin film.

According to an exemplary embodiment of the present invention, as the reference electrode and the counter electrode, an electrode commonly used when an electrochemical cell is constructed may be used. For example, a silver-silver chloride (Ag/AgCl) electrode may be used as the reference electrode, and a platinum material electrode may be used as the counter electrode.

According to an exemplary embodiment of the present invention, as a means for applying current or voltage to the electrochemical cell, a voltage or a current applying device may be used, and the means may be, for example, a potentiostat capable of setting the applied voltage or current. The method of applying voltage may be a potentiostatic method, a cyclic voltammetry method, or a method in which two voltages already set in a voltage pulse format are alternately and repeatedly applied for a set time, and the method of applying current may be a galvanostatic method or a method in which two currents already set in a pulse format are alternately and repeatedly applied for a set time.

Another exemplary embodiment of the present invention provides a CIS-based thin film manufactured using the method.

Still another exemplary embodiment of the present invention provides a thin film solar cell including the CIS-based thin film as a light absorption layer.

According to an exemplary embodiment of the present invention, the thin film solar cell may be a bottom cell of a tandem solar cell. Further, according to an exemplary embodiment of the present invention, the thin film solar cell is a tandem solar cell, and the CIS-based thin film may be included as a light absorption layer of a bottom cell. The top cell of the tandem solar cell may include a perovskite layer as a light absorbing layer, and the CIS-based thin film may be surface-flattened without mechanical and chemical damage by electropolishing, thereby easily applying a perovskite top cell onto the CIS-based bottom cell by a solution process.

As described above, the CIS-based thin film manufactured by the method has low surface roughness without mechanical or chemical damage, so that when the CIS-based thin film is applied to a tandem solar cell, a separate process for smoothness of junction part (recombination layer) does not need to be performed, and the CIS-based thin film has an effect of enabling conformal film deposition during the formation of a perovskite top cell.

Hereinafter, the present invention will be described in detail with reference to Examples for specifically describing the present invention. However, the Examples according to the present invention may be modified into various different forms, and it should not be interpreted that the scope of the present invention is limited to the Examples to be described below. The Examples of the present specification are provided for more completely describing the present invention to those with ordinary skill in the art.

### Comparative Example 1

1.1 mm thick soda-lime glass was coated with molybdenum and used as a working electrode, and a CIS-based compound layer was formed using an electrochemical deposition method. In this case, as an electrolyte solution, 0.24 M potassium chloride, 12 mM sulfamic acid, 12 mM potassium hydrogen phthalate, 2.4 mM copper(II) chloride dihydrate, 5.2 mM selenium dioxide, and 9.6 mM indium chloride were dissolved in distilled water and mixed for a sufficient time, and the resulting mixture was used. As a counter electrode and a reference electrode, a platinum plate and a silver-silver chloride (Ag/AgCl) electrode were used, and a voltage of −0.54 V relative to reference electrode was applied to the working electrode for 5400 seconds. The manufactured CIS-based compound layer was sintered in a tubular electric furnace at 580° C. for 30 minutes. During the process, argon gas was flowed at 100 sccm, and selenium was put into an alumina crucible, and heated at a temperature of 360° C. to supply selenium.

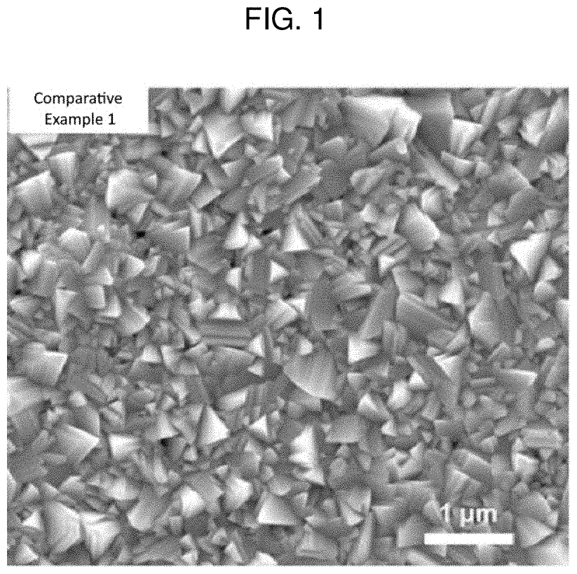

FIG. 1 illustrates a scanning electron microscope (SEM) image of the surface of a CIS-based compound layer manufactured as in Comparative Example 1. According to FIG. 1, it could be confirmed that the surface of the CIS-based compound layer that had not been separately surface-treated was very rough.

### Comparative Example 2

An electrolyte solution was prepared by dissolving 0.24 M potassium chloride, 12 mM sulfamic acid, 12 mM potassium hydrogen phthalate, 5.2 mM selenium dioxide, 2.4 mM copper(II) chloride dihydrate and 9.6 mM indium chloride in distilled water. An electrochemical cell was constructed using a conductive base material including a CIS-based compound layer manufactured as in Comparative Example 1 as a working electrode, a platinum plate as a counter electrode, a silver-silver chloride (Ag/AgCl) electrode as a reference electrode, and the electrolyte solution.

And then, during electropolishing, the solution temperature was maintained at 27° C., and the solution was not stirred. When electropolishing was performed by applying a constant voltage, the electropolishing was performed by setting the applied voltage in a range of 0.25 V to 0.65 V relative to the reference electrode, and the application time to 10 minutes.

As a result of Comparative Example 2, a change in surface morphology of the CIS-based compound layer observed in an applied voltage range of 0.32 V or less was not clearly shown. Furthermore, it was observed that when the applied voltage was 0.5 V or more, a change in surface morphology began to appear, but it was observed that as the applied voltage was increased, a molybdenum layer, which is a conductive base material, was damaged, and the current value flowing by the applied voltage did not converge to a constant value and continuously increased or decreased to a very low value over time.

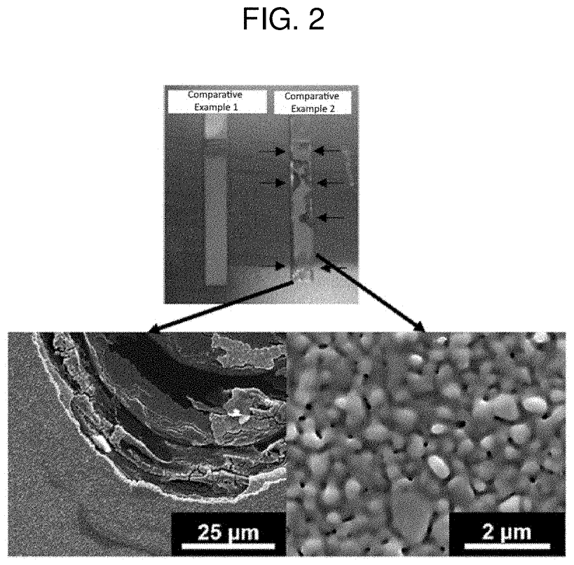

FIG. 2 illustrates the results according to electropolishing in Comparative Example 2. Specifically, as a result of performing electropolishing at an applied voltage of 0.6 V, it could be confirmed that a peeling phenomenon of the CIS-based compound layer due to damage to the conductive base material occurred. Furthermore, it could be confirmed that the surface microstructure of the CIS-based compound layer severely deteriorated.

According to the results in FIG. 2, it was confirmed that when electropolishing was performed to flatten the CIS-based compound layer, the range of applied voltage that could be applied was limited, and in the case of exceeding the applied voltage range, the surface microstructure deteriorated along with a phenomenon in which the CIS-based compound layer peeled off. Furthermore, a problem was also found in which the degree of surface planarization by electropolishing in the above-described electrolyte composition was inconsistent.

### Example

Electropolishing of the CIS-based compound layer was performed in the same manner as in Comparative Example 2, except that ethanol was mixed with an electrolyte solution for electropolishing in a content of 2 vol % or 5 vol %, and the applied voltage and the time were adjusted to 0.6 V and 10 minutes, respectively.

For reference, the pH of the electrolyte solution according to the content of ethanol is shown in the following Table 1.

TABLE 1

| Content of ethanol (vol %) | Electrolyte solution pH |
|---|---|
| 0 | 2.2 |
| 1 | 2.2 |
| 2 | 2.1 |
| 5 | 2.1 |
| 10 | 2.0 |

According to Table 1, it could be confirmed that the pH of the electrolyte solution was significantly decreased when the content of ethanol exceeded 10 vol %, and it was determined that in order to minimize a change in pH of the electrolyte solution, an ethanol content of less than 10 vol %, specifically, 5 vol % or less was appropriate.

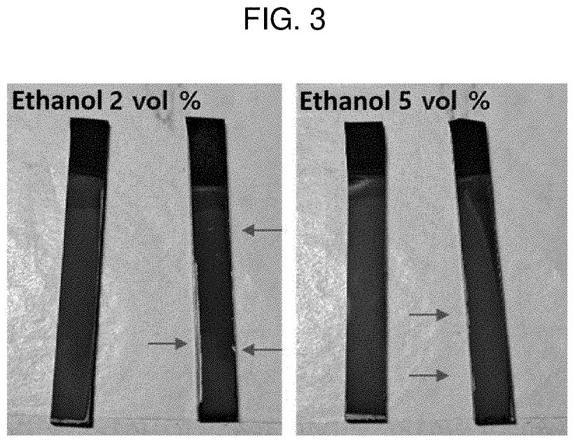

FIG. 3 illustrates the electropolishing results of the CIS-based compound layer in the Example according to the content of ethanol. According to FIG. 3, it could be confirmed that when ethanol was added to the electrolyte solution as in the Example, the peeling phenomenon of the CIS-based compound layer due to the damage of the conductive base material was extremely reduced, and it could be confirmed that particularly in the case where the content of ethanol was 5 vol %, the CIS-based compound layer was hardly damaged even when the applied voltage was 0.6 V.

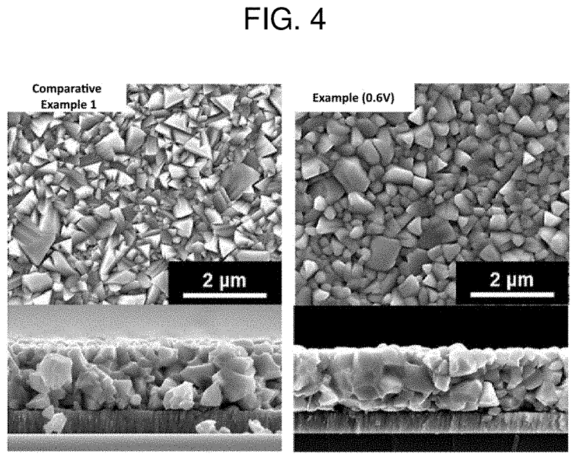

FIG. 4 illustrates the surface and cross-sectional scanning electron microscope (SEM) images of CIS-based compound layers according to Comparative Example 1 and the Example (0.6 V). According to FIG. 4, it can be confirmed that the surface of the CIS-based compound layer according to the Example is very flat compared to the surface of the CIS-based compound layer of Comparative Example 1 which has not been electropolished.

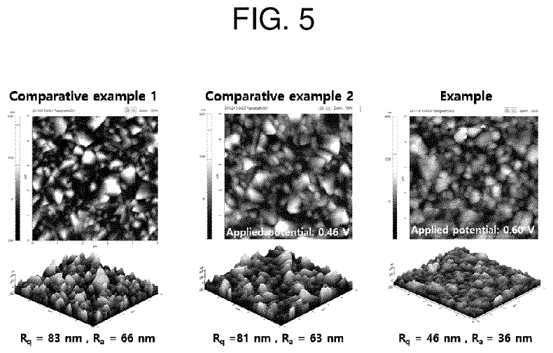

Furthermore, FIG. 5 illustrates the results of measuring the surface roughnesses of the CIS-based compound layers according to Comparative Example 1, Comparative Example 2, and Example, using an atomic force microscope (AFM). The results thereof are shown in the following Table 2.

TABLE 2

| | Comparative | Comparative | | | |
|---|---|---|---|---|---|
| | Example 1 | Example 2 | | Example 1 | |
| Applied voltage | — | 0.46 | V | 0.6 | V |
| Ra roughness | 66 nm | 63 | nm | 36 | nm |

According to the results in FIG. 5 and Table 2, when electropolishing was performed using an electrolyte solution to which ethanol was added, the durability of the CIS-based compound layer was improved compared to the basic electrolyte, so that the applied voltage range during electropolishing could be widened without a peeling phenomenon of the CIS-based compound layer. It is considered that the ethanol added to the electrolyte solution protects the CIS-based compound layer from being damaged due to oxidation of the molybdenum base material. In addition, it could be observed that the surface roughness of the CIS-based compound layer became very low after electropolishing according to the ethanol added to the electrolyte solution. From the fact that when an ethanol additive is used, the magnitude of the current measured during the electropolishing process is smaller under the same applied voltage conditions, it is assumed that as the thickness of the diffusion layer between the thin film and the electrolyte is increased by surface adsorption of the CIS-based compound layer of ethanol, which is an additive, the anodic oxidation rate is decreased.

1. A method for planarizing a CIS-based thin film, the method comprising: electropolishing a CIS-based compound layer by applying current or voltage to an electrochemical cell comprising: a CIS-based compound layer provided on a conductive base material, as a working electrode; a counter electrode; and an electrolyte solution comprising a precursor of elements constituting the CIS-based compound layer, a supporting electrolyte, a complexing agent, and an additive comprising a hydroxy functional group.

2. The method of claim 1, wherein the additive comprising the hydroxy functional group is a C1 to C10 alcohol.

3. The method of claim 1, wherein a content of the additive comprising the hydroxy functional group is 0.5 vol % to 20 vol % in the electrolyte solution.

4. The method of claim 1, wherein the applied voltage (vs. Ag/AgCl) in the electropolishing step is 0.4 V to 0.8 V.

5. The method of claim 1, wherein the electropolishing step is performed for 5 minutes to 150 minutes.

6. The method of claim 1, wherein a pH of the electrolyte solution is 2.0 to 2.2.

7. The method of claim 1, wherein the CIS-based compound layer comprises a copper indium selenide (CIS) compound, a copper indium gallium selenide (CIGS) compound, or a copper zinc tin sulfide (CZTS) compound.

8. The method of claim 1, wherein the precursor is a chloride, sulfate, nitrate, acetate or hydroxide of a metal selected from the group consisting of In, Ga, Zn, Sn, Al, and an alloy thereof, or SeO₂, H₂SeO₃, or SeCl₄.

9. A CIS-based thin film manufactured using the method of claim 1.

10. A thin film solar cell comprising the CIS-based thin film of claim 9 as a light absorption layer.

11. The thin film solar cell of claim 10, wherein the thin film solar cell is a tandem solar cell, and the CIS-based thin film is comprised as a light absorption layer of a bottom cell.
